(19) United States
(12) Patent Application Publication
(10) Pub. No.: US 2011/0065028 A1
(43) Pub. Date: Mar. 17, 2011

(54) PATTERN GENERATING METHOD, MANUFACTURING METHOD OF MASK, AND MANUFACTURING METHOD OF SEMICONDUCTOR DEVICE

(76) Inventors: Katsuyoshi KODERA, Kanagawa (JP); Satoshi TANAKA, Kanagawa (JP); Toshiya KOTANI, Tokyo (JP); Soichi INOUE, Kanagawa (JP)

(21) Appl. No.: 12/874,756

(22) Filed: Sep. 2, 2010

(30) Foreign Application Priority Data
Sep. 11, 2009 (JP) 2009-210716

(51) Int. Cl. G03F 1/00; G03F 7/20

(52) U.S. Cl. 430/5; 430/319; 430/30; 430/322

(57) ABSTRACT

According to the embodiments, each of a main pattern of a mask to be transferred onto a substrate by using a lithography process, a first assist pattern that improves a resolution of an on-substrate pattern obtained by transferring the main pattern onto the substrate, and a second assist pattern that suppresses a transfer property of the first assist pattern onto the substrate is placed as a mask pattern.

### CROSS-REFERENCE TO RELATED APPLICATIONS

This application is based upon and claims the benefit of priority from the prior Japanese Patent Application No. 2009-210716, filed on Sep. 11, 2009; the entire contents of which are incorporated herein by reference.

### FIELD

The present embodiments typically relate to a pattern generating method, a manufacturing method of a mask, and a manufacturing method of a semiconductor device.

### BACKGROUND

In recent years, with the miniaturization of a pattern constituting a semiconductor device, it has become difficult to ensure a sufficient process margin only by fine adjustment of a main pattern. Therefore, recently, a layout design using an assist pattern (SRAF: Sub-Resolution Assist Feature) is used. The assist pattern is desired to be placed with a sufficiently large size to sufficiently ensure the process margin of the main pattern (lithography target) while satisfying mask constraints.

When a lithography inspection is performed in a state where such a large assist pattern is placed, the assist pattern is transferred onto a substrate in some cases. In such a case, conventionally, the size of the assist pattern in an area in which a problem occurs is reduced to a size so that the assist pattern is not transferred onto the substrate. However, when the assist pattern size is made small, because the assist pattern itself contributes to improvement of the resolution of the main pattern, the resolution of the main pattern degrades (process latitude decreases). Moreover, in a state where pattern integration is high and a distance within which an optical proximity effect affects is long, when the assist pattern size is simply reduced, a sidelobe transfer newly occurs at a position different from the reduced assist pattern in some cases.

### BRIEF DESCRIPTION OF THE DRAWINGS

FIG. 1 is a diagram for explaining a concept of an SRAF placing method according to a first embodiment;

FIG. 2A to FIG. 2C are diagrams for explaining an aerial image intensity when an SRAF is placed by the SRAF placing method according to the first embodiment;

FIG. 3 is a block diagram illustrating a configuration of an SRAF placing system;

FIG. 4 is a flowchart illustrating a process procedure of an SRAF placement;

FIG. 5 is a diagram illustrating an example of an interference map;

FIG. 6 is a block diagram illustrating a configuration of an SRAF size changing system;

FIG. 7 is a diagram for explaining a size changing process of a resolution improving SRAF;

FIG. 8 is a diagram for explaining a placement position changing process of the resolution improving SRAF;

FIG. 9 is a diagram for explaining a placement position changing process of a transfer suppressing SRAF; and

FIG. 10 is a diagram illustrating a hardware configuration of a second-SRAF placing apparatus.

### DETAILED DESCRIPTION

According to the embodiments, each of a main pattern of a mask to be transferred onto a substrate by using a lithography process, a first assist pattern that improves a resolution of an on-substrate pattern obtained by transferring the main pattern onto the substrate, and a second assist pattern that suppresses a transfer property of the first assist pattern onto the substrate is placed as a mask pattern.

A pattern generating method, a manufacturing method of a mask, and a manufacturing method of a semiconductor device according to the embodiments will be explained below in detail with reference to the accompanying drawings. The present invention is not limited to these embodiments.

### First Embodiment

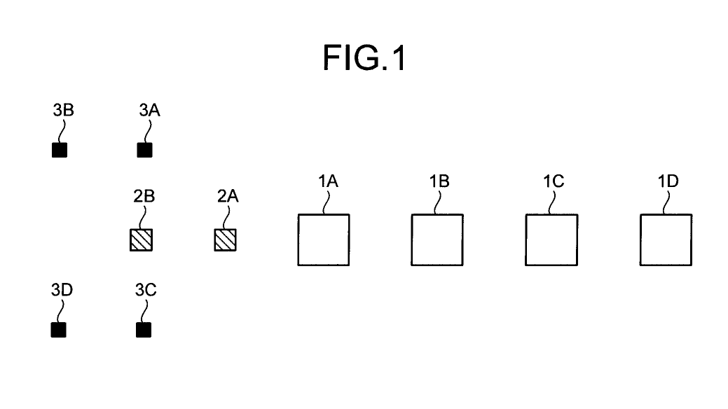

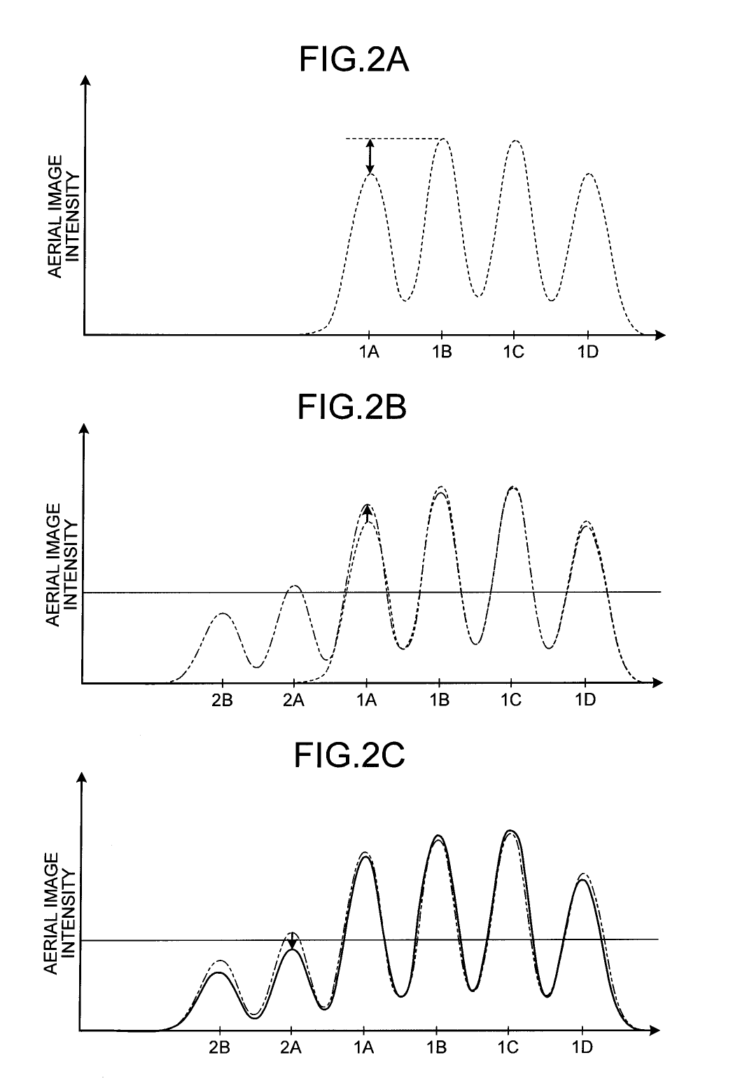

FIG. 1 is a diagram for explaining a concept of an SRAF placing method according to the first embodiment. FIG. 2A to FIG. 2C are diagrams for explaining an aerial image intensity when an SRAF is placed by the SRAF placing method according to the first embodiment.

When generating a mask pattern used in a lithography process of a semiconductor device, a lithography target (=main pattern) is generated by using design layout data. Then, an OPC (Optical Proximity Correction) process is performed as needed on a mask pattern layout (pre-OPC mask pattern) in which an assist pattern is placed in the lithography target (=main pattern) for improving a process margin of the main pattern to generate the mask pattern (first mask pattern). The process margin of the main pattern is improved, so that the resolution of the main pattern is improved.

In the pre-OPC mask pattern, main patterns 1A to 1D that need to be transferred onto a substrate such as a wafer and a first SRAF (first assist pattern) are placed. The first SRAF is the assist pattern (hereinafter, resolution improving SRAFs 2A and 2B) that affects the shapes of the main patterns 1A to 1D when forming the main patterns 1A to 1D on a wafer. The resolution improving SRAFs 2A and 2B are placed at pattern placement positions (positions on a mask) that improve the resolution of the main patterns 1A to 1D. The main patterns 1A to 1D in this example are patterns, for example, with the same size and shape that are placed periodically (with predetermined intervals).

For example, when the main patterns 1A to 1D are placed periodically, the main patterns 1A and 1D placed at the periodic ends have an aerial image intensity at a wafer exposure lower than the main patterns 1B and 10, so that the process margin is low (FIG. 2A). Therefore, the SRAF for increasing the aerial image intensity of the main patterns 1A and 1D is placed near the main patterns 1A and 1D. In the present embodiment, the case is explained in which the resolution improving SRAFs 2A and 2B for increasing the aerial image intensity of the main pattern 1A are placed near the main pattern 1A.

When the resolution improving SRAFs 2A and 2B are placed near the main pattern 1A, the aerial image intensity of the main pattern 1A is increased to the same degree as the aerial image intensity of the main patterns 1B and 1C, so that the process margin of the main pattern 1A is increased to the same degree as the aerial image intensity of the main patterns 1B and 10 (FIG. 2B).

However, in the case where the resolution improving SRAF 2A has the aerial image intensity equal to or more than a predetermined value, the resolution improving SRAF 2A is transferred onto a wafer. Thus, in the present embodiment, a second SRAF (assist pattern that prevents transfer of the first assist pattern) that decreases the aerial image intensity of the resolution improving SRAF 2A while ensuring the aerial image intensity of the main pattern 1A is placed near the main pattern 1A. The second SRAF is the assist pattern (hereinafter, transfer suppressing SRAFs 3A to 3D) that affects transfer of the resolution improving SRAFs 2A and 2B when forming the main patterns 1A to 1D on a wafer. The transfer suppressing SRAFs 3A to 3D are placed at pattern placement positions (positions on a wafer) that suppress transfer of the resolution improving SRAFs 2A and 2B onto a wafer. Whereby, the main pattern 1A having a desired shape can be formed on a wafer while ensuring a sufficient process margin of the main pattern 1A (FIG. 2C).

In the followings, the main pattern such as the main patterns 1A to 1D is represented by a main pattern 1X in some cases, and the first SRAF such as the resolution improving SRAFs 2A and 2B is represented by a resolution improving SRAF 2X in some cases. Moreover, the second SRAF such as the transfer suppressing SRAFs 3A to 3D is represented by a transfer suppressing SRAF 3X in some cases.

In FIG. 1 and FIG. 2A to FIG. 2C, explanation is given for the case where the main patterns 1X are placed periodically; however, placement of the main patterns 1X is not limited to the periodic placement. Moreover, each of the main patterns 1A to 1D is not limited to the pattern having the same size and shape, and can have any shape and size. Furthermore, a target to place the resolution improving SRAF 2X or the transfer suppressing SRAF 3X is not limited to the main pattern 1A at the periodic end, and the resolution improving SRAF 2X or the transfer suppressing SRAF 3X can be placed for any main pattern 1X.

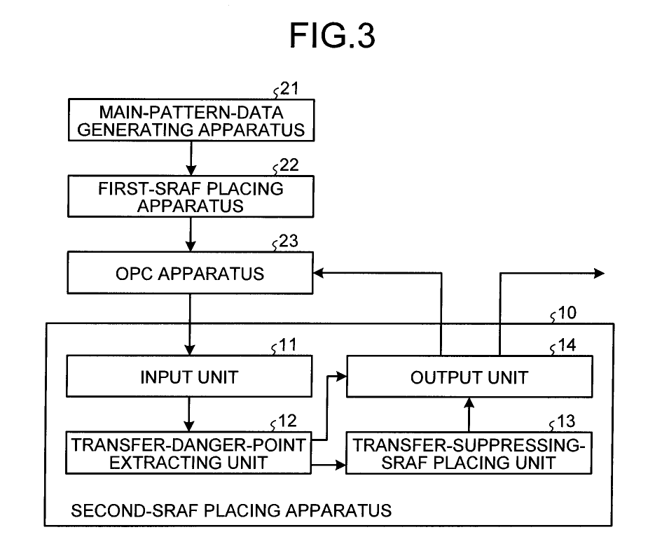

Next, explanation is given for a configuration of a SRAF placing system that places the transfer suppressing SRAF 3X. FIG. 3 is a block diagram illustrating the configuration of the SRAF placing system. The SRAF placing system includes a main-pattern-data generating apparatus 21, a first-SRAF placing apparatus 22, an OPC apparatus 23, and a second-SRAF placing apparatus (assist pattern designing apparatus) 10.

The main-pattern-data generating apparatus 21 is an apparatus that generates the main pattern 1X to be the lithography target by using the design layout data. The first-SRAF placing apparatus 22 is an apparatus that places the resolution improving SRAF 2X near the main pattern 1X or the like by using the main pattern 1X. The OPC apparatus 23 is an apparatus that generates the mask pattern by performing the OPC process on the mask pattern in which the main pattern 1X and the resolution improving SRAF 2X are placed.

The second-SRAF placing apparatus 10 is an apparatus, such as a computer, that verifies whether there is a transfer danger point (pattern failure point that is generated when the mask pattern is transferred onto a wafer) by using the mask pattern on which the OPC process is performed and places the second SRAF in the mask pattern when there is the transfer danger point.

The second-SRAF placing apparatus 10 includes an input unit 11, a transfer danger point extracting unit 12, a transfer-suppressing-SRAF placing unit 13, and an output unit 14. The input unit 11 inputs, for example, the mask pattern after the OPC process in which the main pattern 1X and the resolution improving SRAF 2X are placed. The input unit 11 sends the mask pattern to the transfer danger point extracting unit 12.

The transfer danger point extracting unit 12 verifies whether there is the transfer danger point on a wafer, and, when there is the transfer danger point in the mask pattern, extracts this transfer danger point. The transfer danger point extracting unit 12 calculates the aerial image intensity on a wafer, for example, by a lithography simulation using the mask pattern, verifies whether the strength or the distribution of this aerial image intensity satisfies a desired condition, and extracts a mask pattern portion that does not satisfy the condition as the transfer danger point. The transfer danger point is, for example, a pattern (for example, a transfer pattern of the resolution improving SRAF 2X) formed at a position different from the main pattern 1X by the placement of the resolution improving SRAF 2X. For example, in the case of the aerial image intensity shown in FIG. 2B, because the pattern of the resolution improving SRAF 2A is formed at a position different from the main patterns 1A to 1D, the mask pattern corresponding to this resolution improving SRAF 2A is extracted as the transfer danger point. The transfer danger point extracting unit 12 sends the position of the extracted transfer danger point, the aerial image intensity at the transfer danger point, and the like to the transfer-suppressing-SRAF placing unit 13. Moreover, when there is no transfer danger point in the mask pattern, the transfer danger point extracting unit 12 sends this mask pattern to the output unit 14.

The transfer-suppressing-SRAF placing unit 13 places the transfer suppressing SRAF 3X so that the transfer danger point is eliminated. Specifically, the transfer-suppressing-SRAF placing unit 13 places one to a plurality of the transfer suppressing SRAFs 3X at positions that can prevent generation of the transfer danger point due to transfer of the resolution improving SRAF 2X by decreasing the aerial image intensity of the resolution improving SRAF 2X to be lower than a predetermined value. The transfer-suppressing-SRAF placing unit 13 sends the lithography target in which the main pattern 1X, the resolution improving SRAF 2X, and the transfer suppressing SRAF 3X are placed to the output unit 14.

The output unit 14 outputs the lithography target in which the transfer suppressing SRAF 3X is placed sent from the transfer-suppressing-SRAF placing unit 13 to the OPC apparatus 23 or the like. Moreover, the output unit 14 sends the mask pattern sent from the transfer danger point extracting unit 12 to a mask drawing apparatus (not shown) or the like.

In FIG. 3, the configuration is such that the second-SRAF placing apparatus 10 includes the transfer danger point extracting unit 12; however, the transfer danger point extracting unit 12 can be configured separately from the second-SRAF placing apparatus 10. In this case, the transfer-suppressing-SRAF placing unit 13 places the transfer suppressing SRAF 3X in the mask pattern sent from the transfer danger point extracting unit 12 included in a different apparatus.

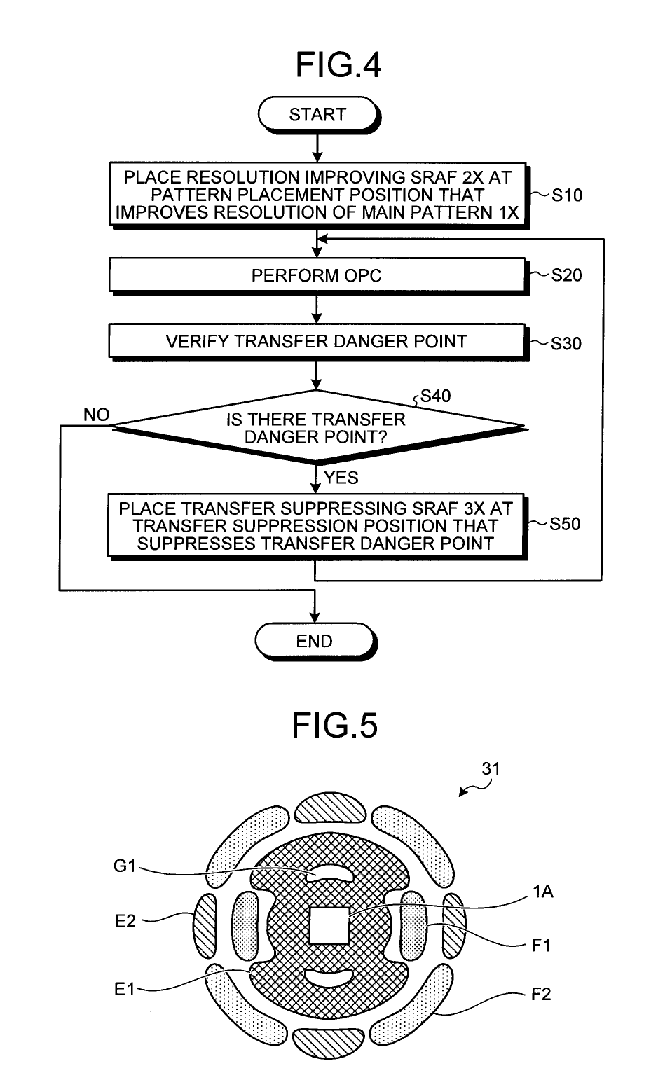

Next, a process procedure of the SRAF placement is explained. FIG. 4 is a flowchart illustrating the process procedure of the SRAF placement. In the SRAF placing system, the main-pattern-data generating apparatus 21 generates the lithography target of the main pattern 1X by using the design layout data.

Thereafter, the first-SRAF placing apparatus 22 places the resolution improving SRAF 2X near the main pattern 1X or the like by using the main pattern 1X. At this time, the first-SRAF placing apparatus 22 calculates the pattern placement position (hereinafter, resolution improvement position) that improves the resolution of the main pattern 1X and places the resolution improving SRAF 2X at the calculated resolution improvement position (Step S10). For example, when the main pattern 1X is the main patterns 1A to 1D shown in FIG. 1, the first-SRAF placing apparatus 22 places the resolution improving SRAFs 2A and 2B as the resolution improving SRAF 2X.

The lithography target in which the resolution improving SRAF 2X is placed by the first-SRAF placing apparatus 22 is sent to the OPC apparatus 23. The OPC apparatus 23 generates the mask pattern by performing the OPC process on the lithography target in which the main pattern 1X and the resolution improving SRAF 2X are placed (Step S20). The OPC apparatus 23 sends the mask pattern on which the OPC process is performed to the second-SRAF placing apparatus 10.

The second-SRAF placing apparatus 10 inputs the mask pattern on which the OPC process is performed from the input unit 11 and sends it to the transfer danger point extracting unit 12. The transfer danger point extracting unit 12 verifies whether there is the transfer danger point in the mask pattern (Step S30).

When there is the transfer danger point in the mask pattern (Yes at Step S40), the transfer danger point extracting unit 12 extracts the transfer danger point. The transfer danger point extracting unit 12 calculates the aerial image intensity on a wafer, for example, by the lithography simulation, and extracts the transfer danger point based on this aerial image intensity. The transfer danger point extracting unit 12 sends the position of the extracted transfer danger point, the aerial image intensity at the transfer danger point, and the like to the transfer-suppressing-SRAF placing unit 13.

The transfer-suppressing-SRAF placing unit 13 places the transfer suppressing SRAF 3X so that the resolution improving SRAF 2X or the like does not become the transfer danger point. Specifically, the transfer-suppressing-SRAF placing unit 13 calculates the pattern placement position (hereinafter, transfer suppression position) that suppresses a transfer property at the transfer danger point, and places the transfer suppressing SRAF 3X at the calculated transfer suppression position (Step S50). Specifically, the transfer-suppressing-SRAF placing unit 13 places the transfer suppressing SRAF 3X at the position that does not cause the resolution of the main pattern 1X to become lower than a predetermined value and can cause the aerial image intensity of the resolution improving SRAF 2X to become smaller than a predetermined value.

For example, when the main pattern 1X and the resolution improving SRAF 2X are the main patterns 1A to 1D and the resolution improving SRAFs 2A and 2B shown in FIG. 1, respectively, the transfer-suppressing-SRAF placing unit 13 places the transfer suppressing SRAFs 3A to 3D as the transfer suppressing SRAF 3X. The transfer-suppressing-SRAF placing unit 13 sends the lithography target in which the main pattern 1X, the resolution improving SRAF 2X, and the transfer suppressing SRAF 3X are placed to the output unit 14.

The output unit 14 outputs the lithography target in which the transfer suppressing SRAF 3X is placed sent from the transfer-suppressing-SRAF placing unit 13 to the OPC apparatus 23 or the like. Thereafter, in the SRAF placing system, the processes at Steps S20 to S40 are repeated. In other words, the OPC apparatus 23 generates the mask pattern by performing the OPC process on the lithography target in which the resolution improving SRAF 2X and the like are placed (Step S20). Then, the transfer danger point extracting unit 12 of the second-SRAF placing apparatus 10 verifies whether there is the transfer danger point in the mask pattern (Step S30).

When there is the transfer danger point in the mask pattern (Yes at S40), the processes at Step S50 and Steps S20 to S40 are repeated until it is determined that there is no transfer danger point in the mask pattern.

On the other hand, when there is no transfer danger point in the mask pattern (No at Step S40), the mask pattern is sent to the output unit 14. The output unit 14 sends the mask pattern sent from the transfer danger point extracting unit 12 to a mask drawing apparatus (not shown) and the like.

In the present embodiment, explanation is given for the case where the first-SRAF placing apparatus 22 places the resolution improving SRAF 2X; however, the second-SRAF placing apparatus 10 can place the resolution improving SRAF 2X. In this case, the transfer-suppressing-SRAF placing unit 13 calculates the resolution improvement position that promotes the SRAF transfer and the transfer suppression position that suppresses the SRAF transfer with respect to the main pattern 1X. The transfer-suppressing-SRAF placing unit 13 can perform calculation of these positions by a rule base or by using a model-based method such as an interference map method.

When the transfer-suppressing-SRAF placing unit 13 calculates the resolution improvement position and the transfer suppression position, the transfer-suppressing-SRAF placing unit 13 places the resolution improving SRAF 2X at the resolution improvement position and places the transfer suppressing SRAF 3X at the transfer suppression position. At this time, in the SRAF placing system, it is applicable that the transfer-suppressing-SRAF placing unit 13 places both of the resolution improving SRAF 2X and the transfer suppressing SRAF 3X simultaneously before performing the OPC process, and thereafter the OPC apparatus 23 performs the OPC process.

When the resolution improvement position and the transfer suppression position are calculated by using the interference map method, the transfer-suppressing-SRAF placing unit 13 generates the interference map with the main pattern 1X as a center. The interference map is generated by using an SRAF model that can ensure a process margin. The transfer-suppressing-SRAF placing unit 13 generates the interference map, for example, by a method described in R. Socha et al., “Contact Hole Reticle Optimization by Using Interference Mapping Lithography (IML™)”, Proc. SPIE 5377 (2004), pp. 222-pp. 240. With this method, an interference map function E(x,y) is calculated by the following Equation (1) by using a function m(x,y) (for example, function defined by a graphic obtained by reducing the size of lithography target data) defined from the shape of the lithography target data (main pattern) that needs to be formed on a wafer.

$$E ( x , y ) = {\sum }_{{x}_{0} , {y}_{0}} m ( {x}_{0} , {y}_{0} ) Φ ( x - {x}_{0} , y - {y}_{0} ) \qquad ( 1 )$$

φ(x,y) in Equation (1) is called an optical kernel function. The mask pattern placed in an area (area in which E(x,y) is a positive value and the absolute value thereof is sufficiently large) in which E(x,y)>>1 increases the image intensity of the main pattern and consequently can improve the process margin of the main pattern. On the other hand, the mask pattern placed in an area (area in which E(x,y) is a negative value and the absolute value thereof is sufficiently large) in which −E(x,y)>>1 decreases the image intensity of the main pattern and degrades the process margin. Therefore, in the present embodiment, the above method is used as follows. Specifically, an interference map function E′(x,y) is calculated by the following Equation (2) by using a function m′(x,v) defined by information on an area in which

$${E}^{′} ( x , y ) = {\sum }_{{x}_{0} , {y}_{0}} {m}^{′} ( {x}_{0} , {y}_{0} ) Φ ( x - {x}_{0} , y - {y}_{0} ) \qquad ( 2 )$$

unintended transfer occurs on a wafer.

With this interference map function E′(x,y), it becomes possible to decrease the image intensity at an unintended transfer point on a wafer by placing the mask pattern in the area in which −E′(x,y)>>1, i.e., the area in which E′(x,y) is a negative value and the absolute value thereof is sufficiently large. In this manner, the degree of interference such as the strength of a transfer promoting effect and the strength of a transfer suppressing effect can be calculated quantitatively by using the interference map function E′(x,y).

FIG. 5 is a diagram illustrating an example of the interference map. FIG. 5 conceptually illustrates part of the interference map with the main pattern 1A as a center. In an interference map 31 shown in FIG. 5, the effect (strength of the transfer promoting effect and strength of the transfer suppressing effect) of an assist pattern placement to a transfer property at a central position of the interference map 31 is illustrated in a divided manner into areas E1, E2, F1, F2, and G1.

In the interference map 31, the area E1 is an area in which the transfer promoting effect is the largest, and the area E2 is an area in which the transfer promoting effect is slightly large. The area F1 is an area in which the transfer suppressing effect is the largest, and the area F2 is an area in which the transfer suppressing effect is slightly large. The area G1 is an intermediate area in which the transfer promoting effect and the transfer suppressing effect are small. In FIG. 5, the strength of the transfer promoting effect and the strength of the transfer suppressing effect are represented by five levels of the areas E1, E2, F1, F2, and G1; however, they can be represented by four or less levels or six or more levels.

The transfer-suppressing-SRAF placing unit 13 can generate a new interference map with the transfer danger point (such as the resolution improving SRAF 2X) as a center. In this case, the resolution improving SRAF 2X is placed based on the interference map generated with the main pattern 1X as a center, and the transfer suppressing SRAF 3X is placed by using the interference map generated with the transfer danger point as a center.

Moreover, explanation is given in FIG. 5 for the interference map in the case where the main pattern 1X is one main pattern 1A; however, the interference map can be calculated with respect to a plurality of the main patterns 1X. For example, when the interference map with respect to one main pattern is indicated by ψ(x,y)=F(x−x1, y−y1), the interference map with respect to two main patterns is indicated by ψ(x,y)=F(x−x1,y−y1)+F (x−x2,y−y2).

Furthermore, it is applicable that after the transfer suppressing SRAFs 3X that decrease the aerial image intensity of the resolution improving SRAF 2X are placed, the transfer suppressing SRAF 3X that decreases the aerial image intensity of the main pattern 1X is eliminated from among these transfer suppressing SRAFs 3X. For example, eight transfer suppressing SRAFs 3X that decrease the aerial image intensity of the resolution improving SRAF 2X are placed, and thereafter, for example, four transfer suppressing SRAFs 3X that decrease the aerial image intensity of the main pattern 1X can be eliminated from among these eight transfer suppressing SRAFs 3X.

Moreover, in the present embodiment, explanation is given for the case of placing the second SRAF (transfer suppressing SRAF 3X) that suppresses transfer of the first SRAF (resolution improving SRAF 2X); however, a third SRAF (third assist pattern) that suppresses transfer of the second SRAF can be further placed. In this case, the third SRAF is placed at the position that decreases the aerial image intensity of the first SRAF or the second SRAF while ensuring the aerial image intensity of the main pattern 1X.

In the similar manner, the (n+1)th SRAF ((n+1)th assist pattern) that suppresses transfer of the n-th (n is natural number) SRAF (n-th assist pattern) can be further placed. In this case, the (n+1)th SRAF is placed at the position that decreases the aerial image intensity of the n-th SRAF and the SRAFs placed before the n-th SRAF while ensuring the aerial image intensity of the main pattern 1X.

Moreover, in the present embodiment, explanation is given for the case of placing the transfer suppressing SRAF 3X at the position that suppresses the SRAF transfer; however, the transfer suppressing SRAF 3X can be placed at the position that suppresses a sidelobe transfer.

When the transfer suppressing SRAF 3X is placed at the position that suppresses the sidelobe transfer, first, the transfer danger point extracting unit 12 extracts the danger point of the sidelobe transfer. The transfer danger point extracting unit 12, for example, performs a latent image calculation based on the mask pattern and extracts the position of the transfer danger point. Next, the transfer-suppressing-SRAF placing unit 13 calculates a mask position (resolution improvement position) through which diffracted light that promotes the sidelobe transfer passes and a mask position (transfer suppression position) through which diffracted light that suppresses the sidelobe transfer passes with respect to the transfer danger point. The transfer-suppressing-SRAF placing unit 13 can calculate these positions by the rule base or by using the interference map method. The transfer-suppressing-SRAF placing unit 13 generates the interference map, for example, with the transfer danger point of the sidelobe transfer as a center. Whereby, the resolution improvement position and the transfer suppression position can be easily distinguished.

The transfer-suppressing-SRAF placing unit 13 places the transfer suppressing SRAF 3X (hole pattern) through which diffracted light can transmit at the transfer suppression position. Alternatively, the transfer-suppressing-SRAF placing unit 13 can place the transfer suppressing SRAF 3X through which diffracted light cannot transmit at the resolution improvement position. Still alternatively, the assist pattern (phase shift pattern) that inverts a phase of light transmitting through a mask can be placed at a mask position corresponding to the resolution improvement position.

The assist pattern placed to eliminate the sidelobe transfer is preferably placed at a position that does not reduce the process margin of the main pattern 1X. The position that does not reduce the process margin of the main pattern 1X can be determined based on the rule base or based on the interference map method.

In this manner, in the SRAF placing system, the transfer suppressing SRAF 3X is placed at the transfer suppression position, so that occurrence of the sidelobe transfer can be prevented without simply reducing the size of the SRAF that improves the resolution of the main pattern 1X, and furthermore the resolution of the main pattern 1X can be improved compared with the conventional technology.

Moreover, the resolution improving SRAF 2X, the transfer suppressing SRAF 3X, the interference map, and the like calculated by the SRAF placing system can be stored in a database. Whereby, the mask pattern can be generated by using information in the database. The resolution improving SRAF 2X, the transfer suppressing SRAF 3X, the interference map, and the like stored in the database can be data calculated based on an actual pattern generated by experiment or the like.

Generation of the mask pattern by the SRAF placing system is performed, for example, for each layer of a wafer process. Then, a semiconductor device (semiconductor integrated circuit) is manufactured by using the mask pattern that is determined to have no transfer danger point (transfer property accepted). Specifically, a product mask is manufactured by using the mask pattern that is determined that the transfer property is accepted, exposure is performed on a wafer on which resist is applied by using the product mask, and thereafter the wafer is developed to form a resist pattern on the wafer. Then, a lower layer film is etched with the resist pattern as a mask. Whereby, an actual pattern corresponding to the mask pattern is formed on the wafer. When manufacturing a semiconductor device, the above described verification of the transfer danger point, placement of the transfer suppressing SRAF 3X, exposure process, development process, etching process, and the like are repeated for each layer.

In this manner, according to the first embodiment, the transfer suppressing SRAF 3X is placed which has an effect of preventing degradation of the process margin of a circuit pattern such as the main pattern 1X and cancelling transfer at the transfer danger point to a wafer, so that an unintended pattern transfer to an area other than the main pattern 1X can be prevented. Thus, a desired main pattern 1X can be transferred onto a wafer at low cost while ensuring the process margin when transferring the main pattern 1X.

Moreover, because the transfer suppressing SRAF 3X is placed by using the interference map generated with the transfer danger point as a center, a desired main pattern 1X can be correctly transferred onto a wafer while ensuring the process margin when transferring the main pattern 1X.

### Second Embodiment

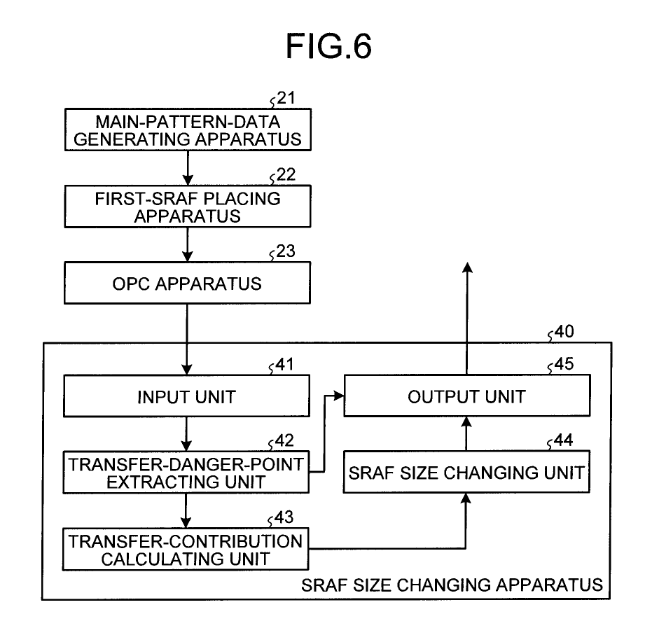

Next, the second embodiment of this invention is explained with reference to FIG. 6 to FIG. 10. In the second embodiment, the size of the resolution improving SRAF 2X is determined based on the promoting and suppressing effects on the sidelobe transfer by the resolution improving SRAF 2X.

In the state where pattern integration is high and the distance within which the optical proximity effect affects is long, even if the resolution improving SRAF 2X or the transfer suppressing SRAF 3X has an effect of suppressing transfer of a pattern that is not intended to be formed, transfer of another unintended pattern may be promoted. The case of promoting transfer of an unintended pattern is, for example, a case of promoting transfer of the SRAF transfer danger point or the sidelobe danger point as explained in the first embodiment.

For example, the case in which the resolution improving SRAF 2X promotes transfer of an unintended pattern is, for example, a case in which the resolution improving SRAF 2X promotes transfer of a pattern other than the main pattern 1X. The case in which the transfer suppressing SRAF 3X promotes transfer of an unintended pattern is, for example, a case in which the transfer suppressing SRAF 3X promotes transfer of a pattern such as the resolution improving SRAF 2X.

Therefore, in the present embodiment, an SRAF size changing system to be described later evaluates the promoting and suppressing effects of the unintended pattern transfer by the resolution improving SRAF 2X or the transfer suppressing SRAF 3X totally and determines the size of the resolution improving SRAF 2X or the transfer suppressing SRAF 3X. In the followings, explanation is given for the case where the SRAF size changing system changes the size of each resolution improving SRAF 2X based on the promoting and suppressing effects on an unintended sidelobe transfer by the resolution improving SRAF 2X.

FIG. 6 is a block diagram illustrating the configuration of the SRAF size changing system. Among components shown in FIG. 6, explanation is omitted for components that are similar to those explained in FIG. 3. The SRAF size changing system includes the main-pattern-data generating apparatus 21, the first-SRAF placing apparatus 22, the OPC apparatus 23, and an SRAF size changing apparatus 40.

The SRAF size changing apparatus 40 is an apparatus, such as a computer, that scores the promoting and suppressing effects of a sidelobe transfer danger degree by the resolution improving SRAF 2X for each transfer danger point by using the mask pattern on which the OPC process is performed and determines the size of the resolution improving SRAF 2X based on this score.

The SRAF size changing apparatus 40 includes an input unit 41, a transfer danger point extracting unit 42, a transfer-contribution calculating unit 43, an SRAF size changing unit 44, and an output unit 45. The input unit 41, the transfer danger point extracting unit 42, and the output unit 45 have functions similar to the input unit 11, the transfer danger point extracting unit 12, and the output unit 14 explained in FIG. 3 in the first embodiment. The transfer danger point extracting unit 42 sends the position of the extracted transfer danger point, the aerial image intensity at the transfer danger point, and the like to the transfer-contribution calculating unit 43.

The transfer-contribution calculating unit 43 calculates the promoting and suppressing effects (hereinafter, transfer contribution) on the sidelobe transfer by the resolution improving SRAF 2X for each transfer danger point. In other words, the transfer-contribution calculating unit 43 scores the transfer contribution to the transfer danger point by the resolution improving SRAF 2X. Specifically, the transfer-contribution calculating unit 43 calculates a distribution of the transfer contributions with respect to a certain transfer danger point on the mask pattern data, and determines the sum of the transfer contributions on the resolution improving SRAFs 2X as the transfer contribution at the transfer danger point. The sum of the transfer contributions is calculated by integrating the transfer contributions in areas of respective resolution improving SRAFs 2X. The transfer-contribution calculating unit 43 can calculate the transfer contribution by using the rule base or calculate quantitatively based on the intensity of the interference map. The transfer-contribution calculating unit 43 sends the transfer contribution calculated for each transfer danger point to the SRAF size changing unit 44.

The SRAF size changing unit 44 determines whether to enlarge or reduce the size of the resolution improving SRAF 2X or whether to change the size of the resolution improving SRAF 2X based on the transfer contribution for each transfer danger point and the distribution of the transfer contributions. For example, the transfer-contribution calculating unit 43 scores the transfer contribution when the size of the resolution improving SRAF 2X is enlarged or reduced for each transfer danger point. Then, the size of the resolution improving SRAF 2X is enlarged or reduced so that the transfer contribution falls within the range of a predetermined score.

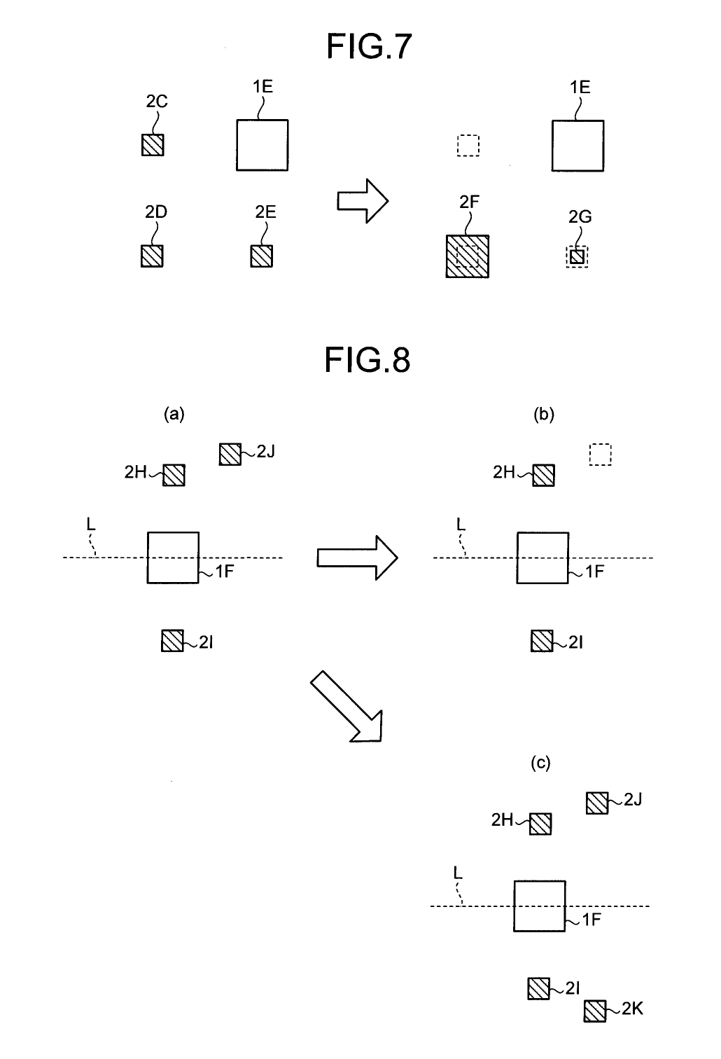

FIG. 7 is a diagram for explaining a size changing process of the resolution improving SRAF. FIG. 7 illustrates the mask pattern after the OPC, in which a main pattern 1E and resolution improving SRAFs 2C to 2E are placed. The resolution improving SRAFs 2C to 2E are placed at the pattern placement positions that improve the resolution of the main pattern 1E. However, the resolution improving SRAFs 2C to 2E degrade the resolution of a not-shown main pattern 1X other than the main pattern 1E in some cases. Therefore, in the present embodiment, the SRAF size changing apparatus 40 prevents degradation of the resolution of the main pattern 1X by enlarging or reducing the resolution improving SRAFs 2X that degrade the resolution of the main pattern 1X.

At this time, the SRAF size changing apparatus 40 enlarges or reduces the resolution improving SRAFs 2X so that the resolution of the main pattern 1E is not degraded. In other words, the SRAF size changing unit 44 determines the optimum size of the resolution improving SRAFs 2X based on the sidelobe transfer effect (transfer contribution) by the resolution improving SRAFs 2X at the main pattern 1E and the sidelobe transfer effect by the resolution improving SRAFs 2X at all of the transfer danger points.

FIG. 7 illustrates the case where the resolution improving SRAF 2D is enlarged into a resolution improving SRAF 2F and the resolution improving SRAF 2E is reduced into a resolution improving SRAF 2G. In this manner, the size of the resolution improving SRAF 2X is changed, so that it is possible to prevent a problem that the sidelobe is generated at another transfer danger point. In other words, the SRAF size changing unit 44 in the present embodiment prevents degradation of the resolution of other main patterns 1X while maintaining the resolution of the main pattern 1E.

When the resolution improving SRAF 2X is newly placed near the main pattern 1X or the size of the resolution improving SRAF 2X is fine adjusted, even if a symmetrical optical system is used, the placement positions of the resolution improving SRAFs 2X around the main pattern 1X become asymmetric in some cases. This means that an imaging pattern of the main pattern 1X becomes asymmetric.

Therefore, the placement of the resolution improving SRAF 2X can be changed based on not only the transfer contribution to the sidelobe transfer but also the symmetry of the resolution improving SRAFs 2X around the main pattern 1X. For example, when the resolution improving SRAF 2X is placed asymmetrically around the main pattern 1X, the resolution improving SRAF 2X that is placed asymmetrically is eliminated. Whereby, the resolution improving SRAFs 2X can be placed at symmetrical positions (line symmetry or point symmetry) with respect to the main pattern 1X.

FIG. 8 is a diagram for explaining a placement position changing process of the resolution improving SRAF. (a) in FIG. 8 illustrates the mask pattern after the OPC in which a main pattern 1F and resolution improving SRAFs 2H to 2J are placed in the similar manner to FIG. 7.

(b) in FIG. 8 illustrates the case where the SRAF size changing unit 44 deletes the resolution improving SRAF 2J so that the resolution improving SRAFs 2X are placed at positions line symmetrical to the main pattern 1F (symmetrical axis L).

Moreover, (c) in FIG. 8 illustrates the case where the SRAF size changing unit 44 adds a resolution improving SRAF 2K so that the resolution improving SRAFs 2X are placed at positions line symmetrical to the main pattern 1F (symmetrical axis L).

In this manner, the resolution improving SRAF 2X is deleted or added so that the resolution improving SRAFs 2X are placed at positions symmetrical to the main pattern 1X, whereby the main pattern 1X can be formed as a symmetrical imaging pattern.

When the resolution improving SRAFs 2X have various sizes and shapes, the size and shape of the resolution improving SRAFs 2X can be changed so that the resolution improving SRAFs 2X are placed with the size and shape to have symmetry to the main pattern 1X.

Moreover, when the transfer suppressing SRAF 3X is placed at an asymmetrical position to the main pattern 1X, the transfer suppressing SRAF 3X can be added or deleted so that the transfer suppressing SRAFs 3X are placed at positions symmetrical to the main pattern 1X.

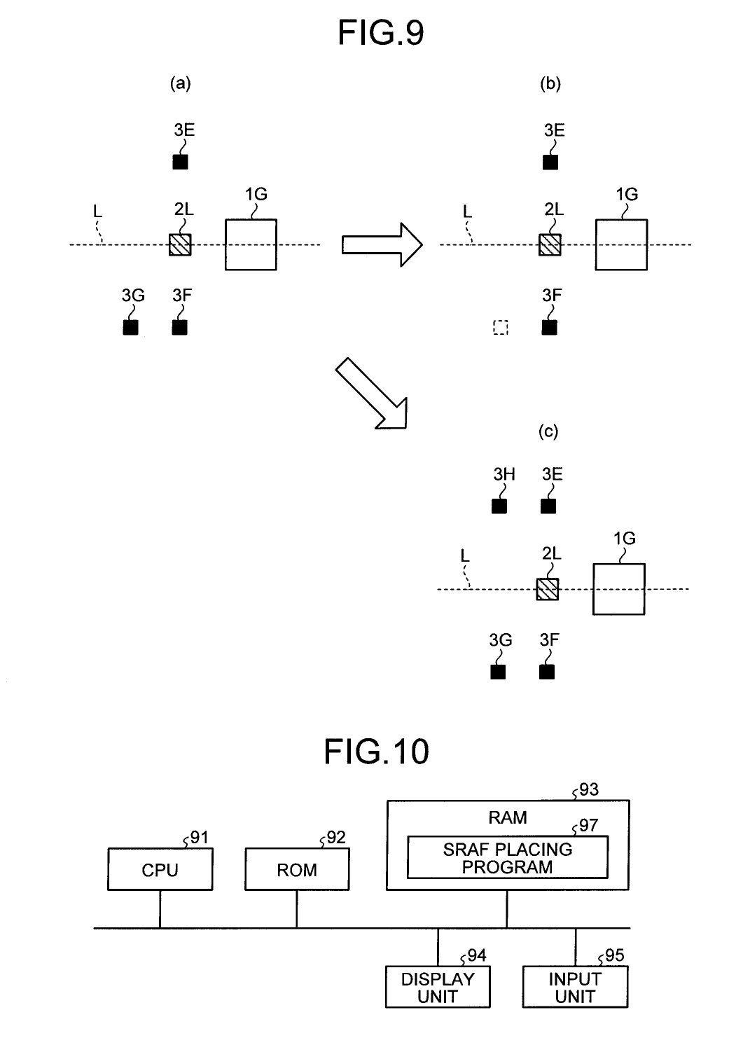

FIG. 9 is a diagram for explaining a placement position changing process of the transfer suppressing SRAF. (a) in FIG. 9 illustrates the mask pattern after the OPC, in which a main pattern 1G, a resolution improving SRAF 2L, and transfer suppressing SRAFs 3E to 3G are placed in the similar manner to FIG. 8.

(b) in FIG. 9 illustrates the case where the SRAF size changing unit 44 deletes a transfer suppressing SRAF 3G so that the transfer suppressing SRAFs 3X are placed at positions line symmetrical to the main pattern 1G (symmetrical axis L).

Moreover, (c) in FIG. 9 illustrates the case where the SRAF size changing unit 44 adds a transfer suppressing SRAF 3H so that the transfer suppressing SRAFs 3X are placed at positions line symmetrical to the main pattern 1X (symmetrical axis L).

In this manner, the transfer suppressing SRAF 3X is deleted or added so that the transfer suppressing SRAFs 3X are placed at positions symmetrical to the main pattern 1X, whereby the main pattern 1X can be formed as a symmetrical imaging pattern.

Next, a hardware configuration of the SRAF size changing apparatus 40 and the second-SRAF placing apparatus 10 explained in the first embodiment is explained. The second-SRAF placing apparatus 10 and the SRAF size changing apparatus 40 have the similar hardware configuration, and the hardware configuration of the second-SRAF placing apparatus 10 is explained in this example.

FIG. 10 is a diagram illustrating the hardware configuration of the second-SRAF placing apparatus. The second-SRAF placing apparatus 10 includes a CPU (Central Processing Unit) 91, a ROM (Read Only Memory) 92, a RAM (Random Access Memory) 93, a display unit 94, and an input unit 95. In the second-SRAF placing apparatus 10, the CPU 91, the ROM 92, the RAM 93, the display unit 94, and the input unit 95 are connected via a bus line.

The CPU 91 executes extraction of the transfer danger point and placement of the transfer suppressing SRAF 3X by using an SRAF placing program 97 that is a computer program. The display unit 94 is a display device such as a liquid crystal monitor, and displays the mask pattern, the transfer danger point, the transfer suppressing SRAF 3X, and the like based on an instruction from the CPU 91. The input unit 95 is configured to include a mouse and a keyboard, and inputs instruction information (such as parameter necessary for placement of the transfer suppressing SRAF 3X) that is externally input by a user. The instruction information input to the input unit 95 is sent to the CPU 91.

The SRAF placing program 97 is stored in the ROM 92 and is loaded in the RAM 93 via the bus line. FIG. 10 illustrates a state where the SRAF placing program 97 is loaded in the RAM 93.

The CPU 91 executes the SRAF placing program 97 loaded in the RAM 93. Specifically, in the second-SRAF placing apparatus 10, the CPU 91 reads out the SRAF placing program 97 from the ROM 92, loads it in a program storage area in the RAM 93, and executes various processes, in accordance with input of an instruction by a user from the input unit 95. The CPU 91 temporarily stores various data generated in the various processes in the data storage area formed in the RAM 93.

The SRAF placing program 97 executed in the second-SRAF placing apparatus 10 has a module configuration including the transfer danger point extracting unit 12 and the transfer-suppressing-SRAF placing unit 13, which are loaded in a main storage device to be generated on the main storage device.

Extraction of the transfer danger point and placement of the transfer suppressing SRAF 3X can be executed by different computer programs. In this case, the CPU 91 executes extraction of the transfer danger point by using a transfer danger point extracting program and executes placement of the transfer suppressing SRAF 3X by using the SRAF placing program 97.

Moreover, the second-SRAF placing apparatus 10 is explained in this example; however, in the case of the SRAF size changing apparatus 40, the CPU 91 executes extraction of the transfer danger point, calculation of the transfer contribution, and the size change of the resolution improving SRAF 2X by using an SRAF size changing program that is a computer program.

In this manner, according to the second embodiment, the optimum size of the resolution improving SRAF 2X is determined based on the main pattern 1E and the transfer contribution by the resolution improving SRAF 2X at the transfer danger point, so that degradation of the resolution at the transfer danger point can be prevented while maintaining the resolution of the main pattern 1E.

Moreover, the resolution improving SRAF 2X is added or deleted so that the resolution improving SRAFs 2X are placed at positions symmetrical to the main pattern 1X, so that the main pattern 1X can be formed as a symmetrical imaging pattern while maintaining the resolution of the main pattern 1X.

### Third Embodiment

In the third embodiment, explanation is given for a pattern correcting method when the sidelobe transfer is detected as a result of a wafer experiment after manufacturing a mask such as the product mask.

After manufacturing the product mask, when a pattern is formed on a wafer by using the product mask, the sidelobe transfer is detected in some cases. In such a case, the sidelobe transfer needs to be eliminated by correcting the mask pattern formed on the product mask. A method of correcting the mask pattern formed on the product mask, for example, includes a method of regenerating the product mask itself by redesigning the design layout and a method of performing fine correction on the product mask by using a technology of focused ion beam, electron beam, or the like.

In the case of performing the fine correction on the product mask, placement of the transfer suppressing SRAF 3X, the size change of the resolution improving SRAF 2X, and the like are performed by using the method explained in the first or second embodiment. At this time, the product mask is adjusted so that the process margin of the main pattern is not degraded and the sidelobe transfer is not generated at a position at which the sidelobe transfer is detected. Whereby, it is possible to generate the product mask in which the sidelobe transfer is prevented. In the present embodiment, the case of correcting the product mask is explained; however, a mask other than the product mask can be corrected.

In this manner, according to the third embodiment, after manufacturing the product mask, placement of the transfer suppressing SRAF 3X and the size change of the resolution improving SRAF 2X are performed in accordance with the placing method of the transfer suppressing SRAF 3X and the size changing method of the resolution improving SRAF 2X explained in the first or second embodiment, so that even after manufacturing the product mask, a desired main pattern 1X can be transferred onto a wafer at low cost while ensuring the process margin when transferring the main pattern 1X.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of generating a pattern, comprising:
placing each of a main pattern of a mask to be transferred onto a substrate by using a lithography process, a first assist pattern that improves a resolution of an on-substrate pattern obtained by transferring the main pattern onto the substrate, and a second assist pattern that suppresses a transfer property of the first assist pattern onto the substrate, as a mask pattern.

2. The method according to claim 1, further comprising:
calculating an area that suppresses a transfer property of the main pattern when a pattern is placed, in a mask area in which the mask pattern is placed, as a first transfer suppressing area; and
placing the second assist pattern in an area other than the first transfer suppressing area.

3. The method according to claim 1, further comprising placing the second assist pattern at a position that does not cause a resolution of the main pattern to become smaller than a predetermined value when the second assist pattern is placed.

4. The method according to claim 1, further comprising:
calculating an area that suppresses the transfer property of the first assist pattern when a pattern is placed, in a mask area in which the mask pattern is placed, as a second transfer suppressing area; and
placing the second assist pattern in the second transfer suppressing area.

5. The method according to claim 2, further comprising determining a size of the first assist pattern based on the first transfer suppressing area.

6. The method according to claim 2, further comprising determining a size of the second assist pattern based on the first transfer suppressing area.

7. The method according to claim 2, further comprising determining a shape of the first assist pattern based on the first transfer suppressing area.

8. The method according to claim 2, further comprising determining a shape of the second assist pattern based on the first transfer suppressing area.

9. The method according to claim 4, further comprising determining a size of the second assist pattern based on the second transfer suppressing area.

10. The method according to claim 4, further comprising determining a shape of the second assist pattern based on the second transfer suppressing area.

11. The method according to claim 1, further comprising placing the first assist pattern to have symmetry to the main pattern.

12. The method according to claim 1, further comprising placing the second assist pattern to have symmetry to the main pattern.

13. The method according to claim 1, further comprising:
extracting an area that causes a resolution of the main pattern to become smaller than a predetermined value when the first assist pattern and the main pattern are placed, in a mask area in which the mask pattern is placed; and
placing the second assist pattern in extracted area.

14. A method of manufacturing a mask, comprising:
placing each of a main pattern of a mask to be transferred onto a substrate by using a lithography process, a first assist pattern that improves a resolution of an on-substrate pattern obtained by transferring the main pattern onto the substrate, and a second assist pattern that suppresses a transfer property of the first assist pattern onto the substrate, as a mask pattern; and
manufacturing the mask by using the mask pattern.

15. The method according to claim 14, further comprising:
calculating an area that suppresses a transfer property of the main pattern when a pattern is placed, in a mask area in which the mask pattern is placed, as a first transfer suppressing area; and
placing the second assist pattern in an area other than the first transfer suppressing area.

16. The method according to claim 14, further comprising placing the second assist pattern at a position that does not cause a resolution of the main pattern to become smaller than a predetermined value when the second assist pattern is placed.

17. The method according to claim 14, further comprising:
calculating an area that suppresses the transfer property of the first assist pattern when a pattern is placed, in a mask area in which the mask pattern is placed, as a second transfer suppressing area; and
placing the second assist pattern in the second transfer suppressing area.

18. A method of manufacturing a semiconductor device, comprising:
placing each of a main pattern of a mask to be transferred onto a substrate by using a lithography process, a first assist pattern that improves a resolution of an on-substrate pattern obtained by transferring the main pattern onto the substrate, and a second assist pattern that suppresses a transfer property of the first assist pattern onto the substrate, as a mask pattern;
manufacturing the mask by using the mask pattern; and
manufacturing a semiconductor device using the mask.

19. The method according to claim 18, further comprising:
calculating an area that suppresses a transfer property of the main pattern when a pattern is placed, in a mask area in which the mask pattern is placed, as a first transfer suppressing area; and
placing the second assist pattern in an area other than the first transfer suppressing area.

20. The method according to claim 18, further comprising:
calculating an area that suppresses the transfer property of the first assist pattern when a pattern is placed, in a mask area in which the mask pattern is placed, as a second transfer suppressing area; and
placing the second assist pattern in the second transfer suppressing area.
